(19) United States
(12) Patent Application Publication
(10) Pub. No.: US 2010/0163934 A1
(43) Pub. Date: Jul. 1, 2010

(54) METHOD FOR FABRICATING A JUNCTION FIELD EFFECT TRANSISTOR AND THE JUNCTION FIELD EFFECT TRANSISTOR ITSELF

(75) Inventor: Chih-Feng Huang, Chupei City (TW)

Correspondence Address: G. LINK CO., LTD., 3550 BELL ROAD, MINOOKA, IL, 60447, US

(73) Assignee: Richtek Technology Corp., ChuPei City (TW)

(21) Appl. No.: 12/418,560

(22) Filed: Apr. 3, 2009

(30) Foreign Application Priority Data
Dec. 26, 2008 (TW) 097150930

(51) Int. Cl. H01L 29/808; H01L 21/337

(52) U.S. Cl. 257/256; 438/186; 257/E29.312; 257/E21.445

(57) ABSTRACT

A method for fabricating a junction field effect transistor includes the steps of the type I semiconductor at the base thereof being doped with the type II semiconductor to form a type II well with a hole; then, a drive-in process of the type II semiconductor is performed to allow the implant dosage of the type II well getting less gradually from the surroundings of the hole toward the center of the hole; and finally, the gate, the source and the drain of the junction field effect transistor being formed successively on the type II well. The implant dosage at the hole, which is acted as a channel, is determined in accordance with the preset size of the hole during the type II well being formed such that it is capable being compatible with the output voltages of different junction field effect transistors to achieve the purpose of the adjustment of the pinch-off voltage of the junction field effect transistor without the need of the mask and the manufacturing process.

### BACKGROUND OF THE INVENTION

1. Field of the Invention

The present invention is related to a field effect transistor (FET) and particularly to a junction field effect transistor (JFET) with which the pinch-off voltage is adjustable easily, and a method for fabricating the junction field effect transistor.

2. Brief Description of the Related Art

Due to the semiconductor technology being developed progressively the digital products such as the computer and the peripherals thereof are capable of being upgraded continuously. The fast change of the manufacturing process for the semiconductor results in a variety of demands for the power source of the integrated circuit (IC) employed in the computer and the peripherals thereof. Hence, various combinations of voltage regulators using such as the boost converter and the buck converter to meet the need of different power sources of the integrated circuit become one of the most important factors to offer versatile digital products.

The junction field effect transistor is the one capable of providing an extremely convenient performance of voltage regulation among various voltage regulating circuits such that it is an excellent choice to select the junction field effect transistor as the prior stage voltage regulator. When the junction field effect transistor is fabricated as the prior stage voltage regulator, the pinch-off voltage of the junction field effect transistor is regulated by means of controlling the implant dosage at the channel of the junction field effect transistor to obtain the desired output voltage of the junction field effect transistor. Although the preceding way achieves the purpose of regulating the output voltage of the junction field effect transistor, it is necessary to have an additional mask and manufacturing process at the time of changing the implant dosage of the channel of the junction field effect transistor for making the voltage regulating circuit. As a result, it makes the fabrication of the voltage regulating circuit more complicated and inconvenient.

### SUMMARY OF THE INVENTION

Accordingly, an object of the present invention is to provide a junction field effect transistor with an adjustable pinch-off voltage and a method for fabricating the junction field effect transistor with which the pinch-off voltage of the junction field effect transistor can be regulated in accordance with different output voltages without applying an additional mask and manufacturing process.

In order to achieve the preceding object, a junction field effect transistor according to the present invention comprises a type II well being disposed on a type I semiconductor base; a type I gate zone being disposed on said type II well; a type I gate contact zone being disposed on said type I gate zone; a type II source contact zone being disposed on said type II well and located at a lateral side of said type I gate zone; and a type II drain contact zone being disposed on said type II well and located at another side of said type I gate zone; wherein the implant dosage of an area located at the type II well beneath the type I gate zone is less than that of the other area of the type II well; and the implant dosage of the aforementioned area is preferably getting less from the surroundings of the aforementioned area toward the center of the aforementioned area.

Further, a method for fabricating a junction field effect transistor according to the present invention comprises following steps: providing a base of a type I semiconductor; doping a type II semiconductor on the base to form a type II well with a hole; performing a process of drive-in for the type II semiconductor being capable of diffusing and entering the hole for the type II well with an implant dosage getting less from the surroundings of the hole toward the center of the hole; doping a type I semiconductor at the type II well at least including an area of the hole to form a type I gate zone; doping a type I semiconductor on the type I gate zone to form a type I gate contact zone with an implant dosage more than that of the type I gate zone; and doping a type II semiconductor on the type II well at two opposite lateral sides of the type I gate zone to form a type II source contact zone and a type II drain contact zone respectively with both implant dosages of the type II source contact zone and the type II drain contact zone being more than that of the type II well. Wherein, the implant dosage at the area of the hole is adjustable in accordance with the size of the hole.

### BRIEF DESCRIPTION OF THE DRAWINGS

The detail structure, the applied principle, the function and the effectiveness of the present invention can be more fully understood with reference to the following description and accompanying drawings, in which:

FIGS. 1A-1F are diagrams illustrating the steps of a method for fabricating a junction field effect transistor according to the present invention;

FIG. 2A is a diagram illustrating the pinch-off of a junction field effect transistor according to the present invention; and

FIG. 2B is a graph illustrating a relation between the drain voltage and source voltage of the junction field effect transistor shown in FIG. 2A.

### DETAILED DESCRIPTION OF THE INVENTION

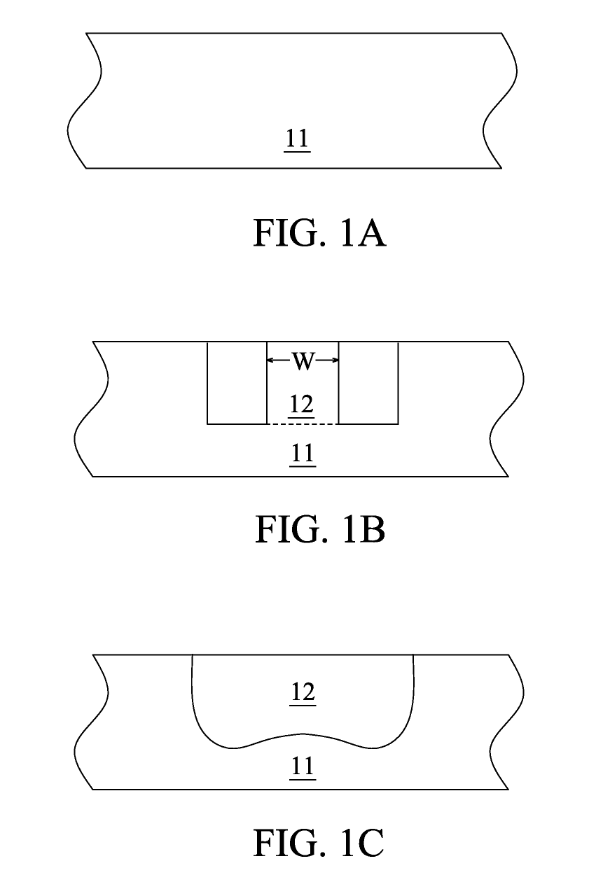

Referring to FIGS. 1A to 1F, the steps of the preferred embodiment of a method for fabricating a junction field effect transistor 10 according to the present invention are illustrated. First, a type I semiconductor base II shown in FIG. 1A is provided and the type I semiconductor base 11 is either N-type semiconductor or P-type semiconductor to fabricate different kinds of the junction field effect transistors. For instance, when a N-type junction field effect transistor is intended to make, the provided type I semiconductor base 11 is the P-type semiconductor and the type II semiconductor, which will be explained afterward, is the N-type semiconductor. Contrarily, when a P-type junction field effect transistor is intended to make, the provided type I semiconductor base 11 is the N-type semiconductor and the type II semiconductor is the P-type semiconductor.

Next, a doping process, which is illustrated in FIG. 1B, is that the type I semiconductor base II is doped with type II semiconductor to form a type II well 12, which has a hole with a width W. The size of the hole is determined in advance at the time of making the shielding layer prior to the process of doping for regulating the implant dosage at the area of the hole such that the pinch-off voltage of the junction field effect transistor 10 can be changed to comply with different output voltages without the need of the additional manufacturing process and mask.

Then, FIG. 1C illustrates a process of drive-in with such as a high temperature hot diffusion to allow the type II semiconductor to diffuse and enter the hole such that the type II well 12 is formed in such a way of the implant dosage getting less from the surroundings of the hole toward the center of the hole so as to constitute a channel of the junction field effect transistor 10.

FIG. 1D illustrates a process of doping type I semiconductor at type II well 12 at least including part of the hole for forming type I gate zone 13 at the junction field effect transistor 10 and on top of the hole.

FIG. 1E illustrates a process of doping type I semiconductor on type I gate zone 13 for making a joint of the type I gate zone 13. Type I gate contact zone 14 is formed with an implant dosage more than type I gate zone 13 for reducing the contact resistance of the lead wire.

FIG. 1F illustrates a process of doping type II semiconductor for making joints of the source and the drain. Type II wells 12 at two opposite lateral sides of type I gate zone 13 form type II drain contact zone 15 and type II source contact zone 16 respectively with an implant dosage more than type II well 12. Finally, the junction field effect transistor 10 with the easily regulated pinch-off voltage is fabricated completely.

Referring to FIG. 1F again, the structure of the finished junction field effect transistor 10 has the type II well 12 with an implant dosage being doped on type I semiconductor base 11 and type I gate zone 13 is arranged on type II well 12, type I gate contact zone 14 being arranged on type I gate zone 13 and type II source contact zone 16 being arranged on type II well 12 at a lateral side of type I gate zone 13, and type II drain contact zone 15 being arranged on type II well 12 disposed at another lateral side of type I gate zone 13. Further, type II semiconductor diffuses and enters the area beneath type I gate zone 13 during the process of the high temperature hot diffusion drive-in such that type II well 12 at the area beneath type I gate zone 13 has an implant dosage less than the surroundings of the area beneath type I gate zone 13.

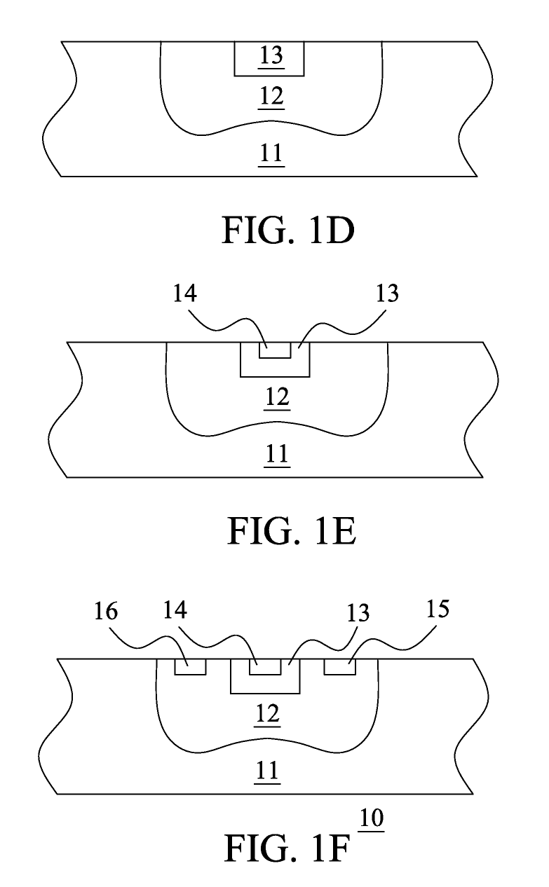

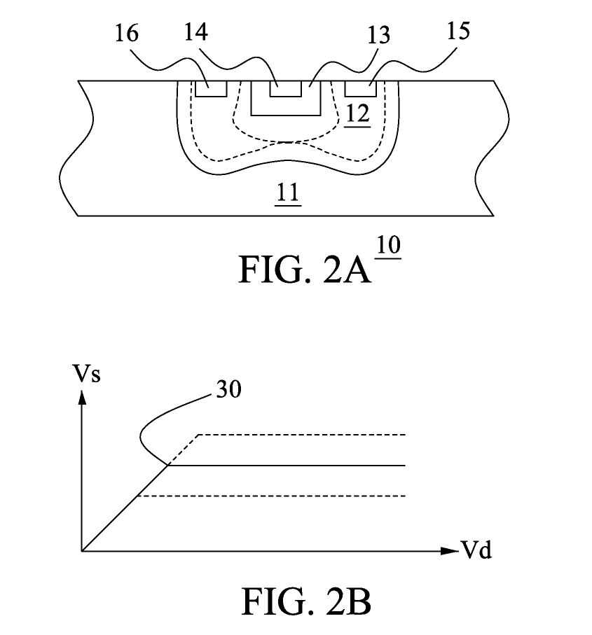

Referring to FIGS. 2A and 2B, how the pinch-off voltage of the junction field effect transistor 10 according to the present invention being regulated is illustrated. In FIG. 2B, when a voltage V_{d} is input via the drain of the junction field effect transistor 10, a voltage Vₛ, which is output via the source, increases with respect to the voltage V_{d} increasing till reaching a pinch-off point 30 shown in FIG. 2B. That is, the voltage Vₛ approaches a constant value without change at the time of a depletion zone confined with dash lines in FIG. 2A being pinched off such that the junction field effect transistor 10 is acted as the prior stage voltage regulator. However, the amount of the voltage Vₛ is fixed to the pinch-off voltage of the junction field effect transistor 10 and the pinch-off voltage of the junction field effect transistor 10 corresponds to the implant dosage of the channel. Hence, simply adjusting the shielding size of the hole at the time of forming the channel well zone changes the actual implant dosage of the channel to achieve the purpose of regulating the output voltage of the junction field effect transistor 10 as the dash lines shown in FIG. 2B.

While the invention has been described with referencing to a preferred embodiment thereof, it is to be understood that modifications or variations may be easily made without departing from the spirit of this invention, which is defined by the appended claims.

What is claimed is:

1. A junction field effect transistor comprising:
a type I semiconductor base;
a type II well being disposed on said type I semiconductor base;
a type I gate zone being disposed on said type II well;
a type I gate contact zone being disposed on said type I gate zone;
a type II source contact zone being disposed on said type II well and located at a lateral side of said type I gate zone; and
a type II drain contact zone being disposed on said type II well and located at another side of said type I gate zone;
characterized in that the implant dosage of an area located at said type II well beneath said type I gate zone is less than that of the other area of said type II well.

2. The junction field effect transistor as defined in claim 1, wherein the implant dosage of said area is getting less from the surroundings of said area toward the center of said area.

3. The junction field effect transistor as defined in claim 1, wherein said type I is referred as a P-type semiconductor and said type II is referred as a N-type semiconductor.

4. The junction field effect transistor as defined in claim 1, wherein said type I is referred as an N-type semiconductor and said type II is referred as a P-type semiconductor.

5. A method for fabricating a junction field effect transistor comprising following steps:
providing a type I semiconductor base;
doping a type II semiconductor on said base to form a type II well with a hole;
performing a process of drive-in for said type II semiconductor being capable of diffusing and entering said hole for said type II well with an implant dosage getting less from the surroundings of said hole toward the center of said hole;
doping a type I semiconductor at said type II well at least including an area of said hole to form a type I gate zone;
doping a type I semiconductor on said type I gate zone to form a type I gate contact zone with an implant dosage more than that of said type I gate zone; and
doping a type II semiconductor on said type II well at two opposite lateral sides of said type I gate zone to form a type II source contact zone and a type II drain contact zone respectively with both implant dosages of said type II source contact zone and said type II drain contact zone being more than that of said type II well.

6. The method for fabricating a junction field effect transistor as defined in claim 5, wherein the implant dosage at an area of said hole is adjustable in accordance with a size of said hole.

7. The method for fabricating a junction field effect transistor as defined in claim 5, wherein said type I is referred as a P-type semiconductor and said type II is referred as an N-type semiconductor.

8. The method for fabricating a junction field effect transistor as defined in claim 5, wherein said type I is referred as an N-type semiconductor and said type II is referred as a P-type semiconductor.

9. The method for fabricating a junction field effect transistor as defined in claim 5, wherein said process of drive-in is a process of high temperature hot diffusion driven-in.
